(19) United States
(12) Patent Application Publication
(10) Pub. No.: US 2015/0179961 A1
(43) Pub. Date: Jun. 25, 2015

(54) ORGANIC ELECTROLUMINESCENCE MATERIAL AND ORGANIC ELECTROLUMINESCENCE DEVICE USING THE SAME

(71) Applicant: SAMSUNG DISPLAY CO., LTD., Yongin-City (KR)

(72) Inventors: Ichinori TAKADA, Yokohama (JP); Hiroyuki NAKAZUMI, Osaka (JP); Shigeyuki YAGI, Osaka (JP)

(21) Appl. No.: 14/629,009

(22) Filed: Feb. 23, 2015

Related U.S. Application Data
(63) Continuation of application No. PCT/KR2013/007884, filed on Sep. 2, 2013.

(30) Foreign Application Priority Data
Aug. 31, 2012 (JP) 2012-192368

(51) Int. Cl. H01L 51/00; C07F 15/00

(52) U.S. Cl. CPC H01L 51/0085; C07F 15/0033; H01L 51/5012

(57) ABSTRACT

An organic electroluminescence material and an organic electroluminescence device, the material being represented by the following Chemical Formula 1:

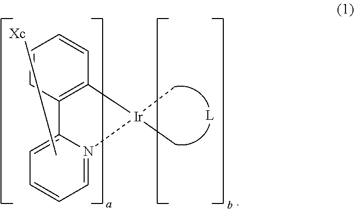

### CROSS-REFERENCE TO RELATED APPLICATIONS

This application is a continuation of pending International Application No. PCT/KR2013/007884, entitled “Organic Electroluminescence Material and Organic Electroluminescence Device Using the Same,” which was filed on Sep. 2, 2013, the entire contents of which are hereby incorporated by reference.

Japanese Patent Application No. 2012-192368, filed on Aug. 31, 2012, in the Japanese Patent Office, and entitled: “Organic Electroluminescence Material and Organic Electroluminescence Device Using the Same,” is incorporated by reference herein in its entirety.

### BACKGROUND

1. Field

Embodiments relate to an organic electroluminescence material, and an organic electroluminescence device using the same.

2. Description of the Related Art

In recent years, an organic electroluminescence display (organic EL display) where an electroluminescence material is used in an electroluminescence device of a display portion has been actively developed. Unlike a liquid crystal display or the like, the organic EL display is so-called a self-luminescent display which recombines holes and electrons injected from a positive electrode and a negative electrode in an emission layer to thus emit light from a light-emitting material including an organic compound of the emission layer, thereby performing display.

### SUMMARY

Embodiments are directed to an organic electroluminescence material, and an organic electroluminescence device using the same.

The embodiments may be realized by providing an organic electroluminescence material represented by the following Chemical Formula 1:

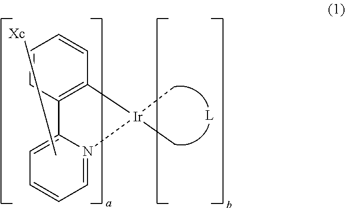

wherein, in Chemical Formula 1, X is a phenylcarbonyl group represented by the following Chemical Formula 2, L is a bidentate ligand represented by one of the following Chemical Formulae 3 to 5, a is 1, 2, or 3, b is 0, 1, or 2, a sum total of a and b is 3, and c is 1 or 2,

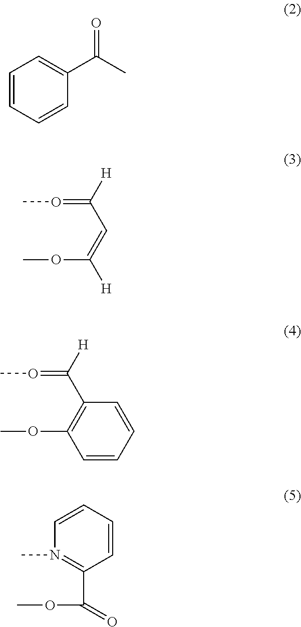

Chemical Formulae 1 to 5 are unsubstituted or substituted, in which case a hydrogen atom thereof is replaced with one of a fluorine atom, a trifluoromethyl group, a cyano group, a nitro group, an alkyl group having 6 or fewer carbon atoms, an aryl group having 6 or fewer carbon atoms, or a heteroaryl group having 6 or fewer carbon atoms.

The phenylcarbonyl group may be bonded at a para position of the phenyl group or the pyridine group, relative to the coordination bond of the phenyl group or the pyridine group with Ir in Chemical Formula 1.

A fluorescence quantum yield of the material may be about 0.4 or more.

The embodiments may be realized by providing an organic electroluminescence device including an organic electroluminescence material represented by the following Chemical Formula 1:

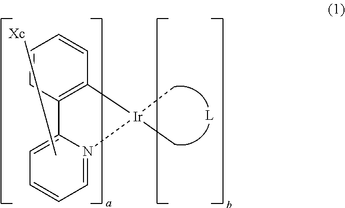

wherein, in Chemical Formula 1, X is a phenylcarbonyl group represented by the following Chemical Formula 2, L is a bidentate ligand represented by one of the following Chemical Formulae 3 to 5, a is 1, 2, or 3, b is 0, 1, or 2, a sum total of a and b is 3, and c is 1 or 2,

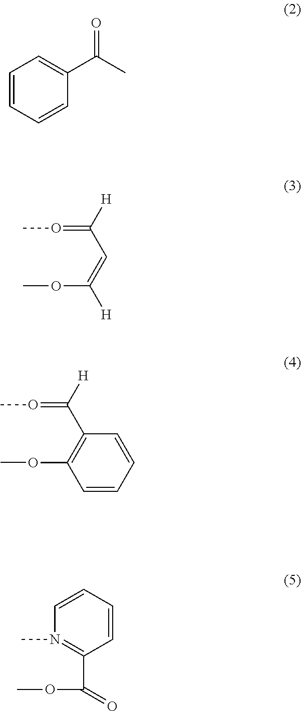

Chemical Formulae 1 to 5 are unsubstituted or substituted, in which case a hydrogen atom thereof is replaced with one of a fluorine atom, a trifluoromethyl group, a cyano group, a nitro group, an alkyl group having 6 or fewer carbon atoms, an aryl group having 6 or fewer carbon atoms, or a heteroaryl group having 6 or fewer carbon atoms.

The phenylcarbonyl group may be bonded at a para position of the phenyl group or the pyridine group, relative to the coordination bond of the phenyl group or the pyridine group with Ir in Chemical Formula 1.

A fluorescence quantum yield of the material may be about 0.4 or more.

### BRIEF DESCRIPTION OF THE DRAWINGS

Features will be apparent to those of skill in the art by describing in detail exemplary embodiments with reference to the attached drawings in which:

FIG. 1 illustrates a schematic view of an example of a structure of an organic EL device;

FIG. 2 illustrates a schematic view of an organic EL device manufactured by using an organic electroluminescence material;

FIG. 3(a) illustrates a graph showing an EL spectrum of an organic EL device manufactured by using the organic electroluminescence material according to an embodiment,

FIG. 3(b) illustrates a graph showing an EL spectrum of an organic EL device manufactured by using the organic electroluminescence material according to another embodiment;

FIG. 4(a) illustrates a graph showing a current density-voltage-brightness curve of an organic EL device manufactured by using the organic electroluminescence material according to an embodiment; and

FIG. 4(b) illustrates a graph showing a current density-voltage-brightness curve of an organic EL device manufactured by using the organic electroluminescence material according to another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

A metal complex compound may include iridium (Ir) as central metal. An Ir (III) metal complex compound having a phenylcarbonyl substituent may be used as a blue-based electroluminescence material in an emission layer of an organic EL device. Thus, emission efficiency of the organic EL device may be improved. Hereinafter, the Ir (III) metal complex compound having the phenylcarbonyl substituent according to an embodiment will be described.

The, e.g., blue-based, organic electroluminescence material according to an embodiment may be represented by the following Chemical Formula 1.

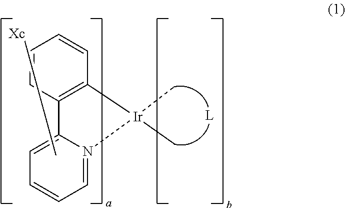

In Chemical Formula 1, X may be a monovalent phenylcarbonyl group represented by the following Chemical Formula 2.

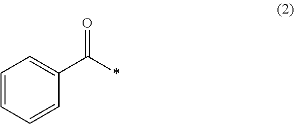 [SMILES: *C(=O)c1ccccc1]

In an implementation, in Chemical Formula 1, X may be substituted or bound at any one of a para positions of the phenyl group or the pyridine ring that is coordinated with Ir (III), or at both sides at the para positions of the phenyl group and the pyridine ring. For example, the phenylcarbonyl group may be bound to the phenyl group at a para position relative to the coordination bond of the phenyl group with the iridium and/or may be bound to the pyridine group at a para position relative to the coordination bond of the pyridine group with the iridium.

In an implementation, in Chemical Formula 1, L may be a bidentate ligand represented by one of the following Chemical Formulae 3 to 5.

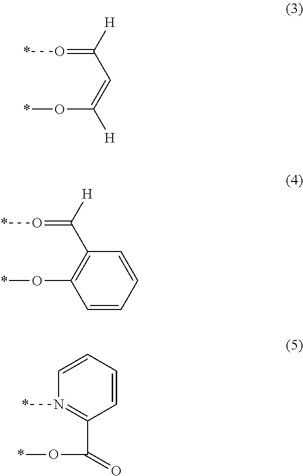

In an implementation, in the compound represented by Chemical Formula 1 (e.g., which includes groups represented by Chemical Formulae 2 to 5) a H atom (H—), a fluorine atom (F—), a trifluoromethyl group (—CF₃), a cyano group (—CN), a nitro group (—NO₂), and an alkyl group, an aryl group, or a heteroaryl group having 6 or less carbon atoms may be each independently substituted by a predetermined number at a predetermined position. For example, in Chemical Formula 1, any suitable hydrogen atom therein may be substituted, e.g., may be replaced by one of a fluorine atom (F—), a trifluoromethyl group (—CF₃), a cyano group (—CN), a nitro group (—NO₂), and an alkyl group, an aryl group, or a heteroaryl group (e.g., having 6 or less carbon atoms)

In Chemical Formula 1, a, b, and c are natural numbers. For example, a sum total of a and b may be 3, a may not be 0, and c may be less than or equal to 2. For example, a may be 1, 2, or 3, b may be 0, 1, or 2, and/or c (e.g., representing a number of X/phenylcarbonyl groups) may be 0, 1, or 2. In an implementation, in Chemical Formulae 2 to 5, * represents a combination position, coordination site, or binding site to a neighboring atom.

The, e.g., blue-based, organic electroluminescence material of according to an embodiment may include the phenylcarbonyl substituent at the para position of the phenylpyridine that is coordinated with central metal Ir (III) (e.g., position 5′ on the phenyl group or position 4 on the pyridine ring as shown below). In an implementation, the organic electroluminescence material according to an embodiment may be an Ir (III) metal complex compound having a basic structure represented by one of the following Chemical Formulae 6 or 7.

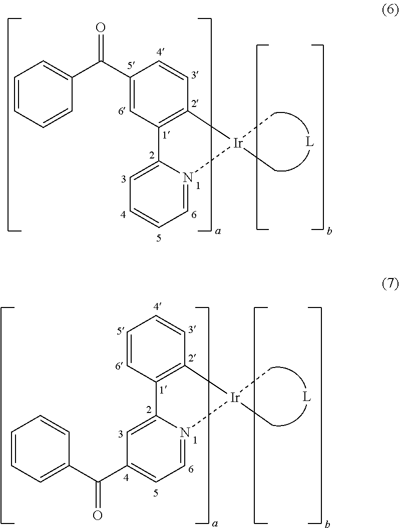

In Chemical Formulae 6 and 7, L may be the same as described with respect to Chemical Formula 1, above, e.g., may be a bidentate ligand represented by one of Chemical Formulae 3 to 5 As shown in Chemical Formulae 6 and 7, in the organic electroluminescence material according to an embodiment, the phenylcarbonyl group may be substituted or bonded at any one of position 5′ on the phenyl group or position 4 on the pyridine ring of phenylpyridine, which are coordinated with central metal Ir (III). In an implementation, the phenylcarbonyl group may be substituted at position 5′ on the phenyl group, and at position 4 (para position with respect to Ir) on the pyridine ring coordinated with central metal Ir (III). In an implementation, the phenylcarbonyl group may be substituted at position 4 on the pyridine ring, and at position 5′ (para position with respect to Ir) on the phenyl group coordinated with central metal Ir (III). In a compound having the basic structure represented by Chemical Formulae 6 and 7, for central metal Ir (III), a metal complex compound in which N atoms are present at both sides of two coordination positions of an auxiliary ligand (e.g., ligand corresponding to L of a base material in Chemical Formula 1) may be unstable, and may not be suitable as an organic electroluminescence material.

Color forming light of the Ir (III) complex compound coordinated with phenylpyridine may have a green color. According to an embodiment, an electron-attracting carbonyl substituent may be introduced at the para position (position 5′ on the phenyl group and/or position 4 on the pyridine ring) of phenylpyridine that is coordinated with central metal Ir (III) to shift a color of color forming light of the Ir (III) metal complex compound from a blue color to a blue-green color. Further, according to an embodiment, a phenyl group may be introduced into or onto the carbonyl group substituted at the para position (position 5′ on the phenyl group and/or position 4 on the pyridine ring) of phenylpyridine coordinated with Ir (III). The Ir (III) complex compound having the phenylcarbonyl substituent at the para position (position 5′ on the phenyl group and/or position 4 on the pyridine ring) of phenylpyridine that is coordinated with central metal Ir (III) may exhibit improved emission efficiency.

In an implementation, the organic electroluminescence material according to an embodiment, e.g., having the phenylcarbonyl substituent at the para position (position 5′ on the phenyl group and/or position 4 on the pyridine ring) of phenylpyridine coordinated with Ir (III), may include one of Compounds 1 to 25 and 27 to 36, below.

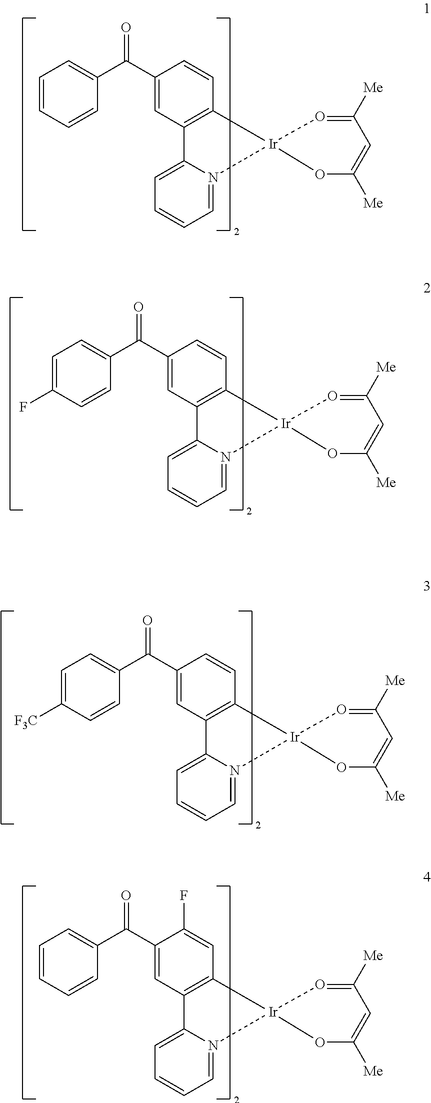

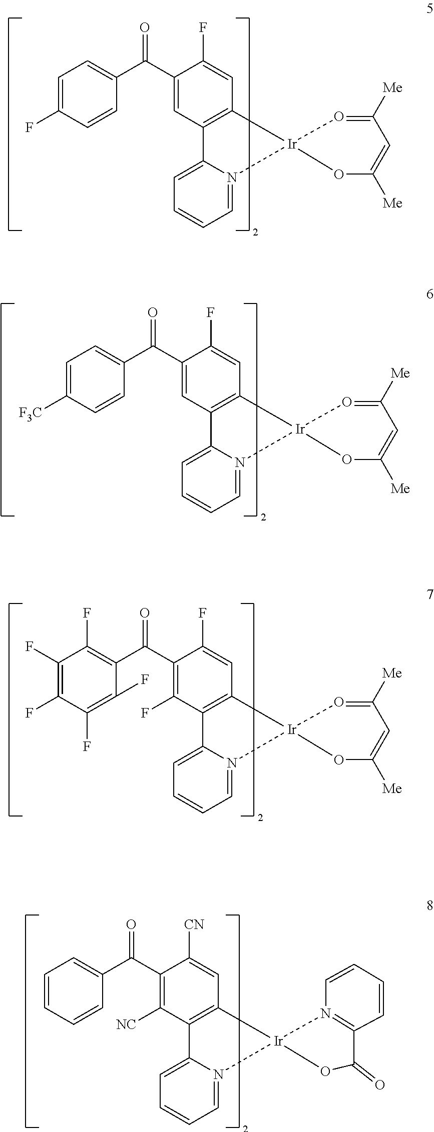

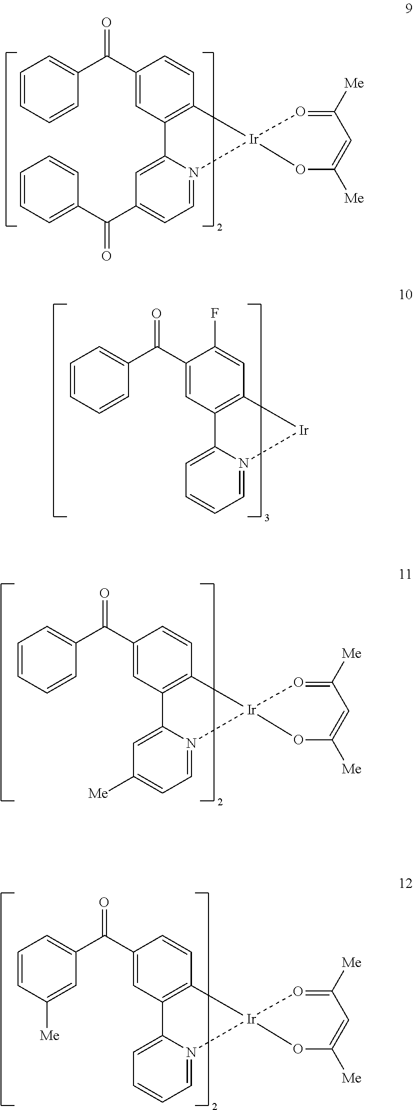

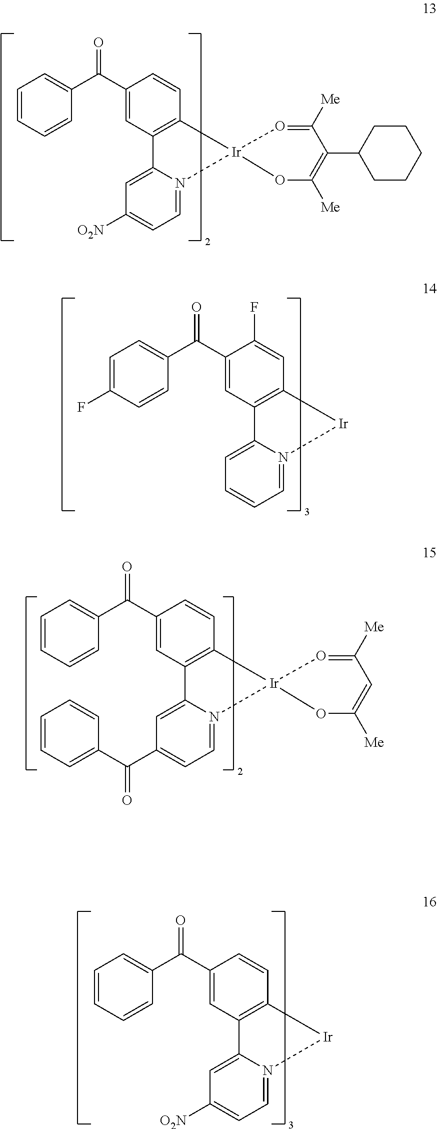

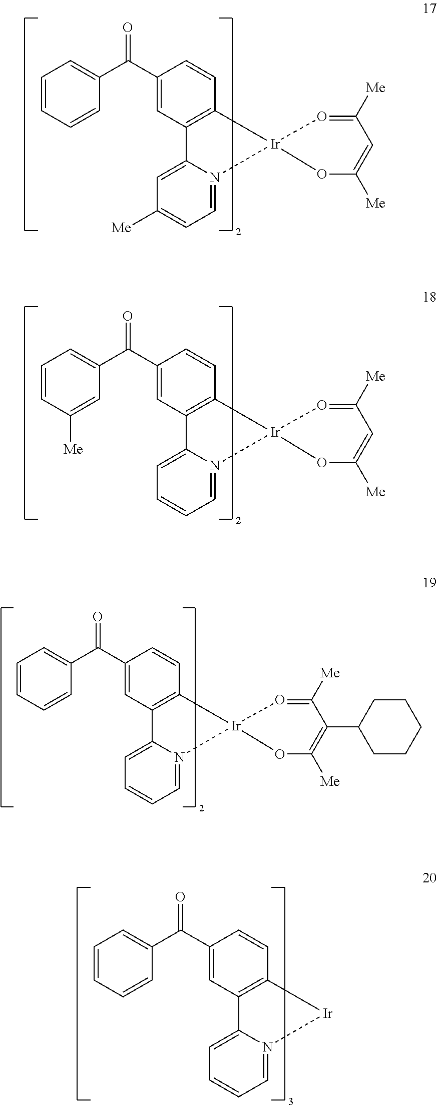

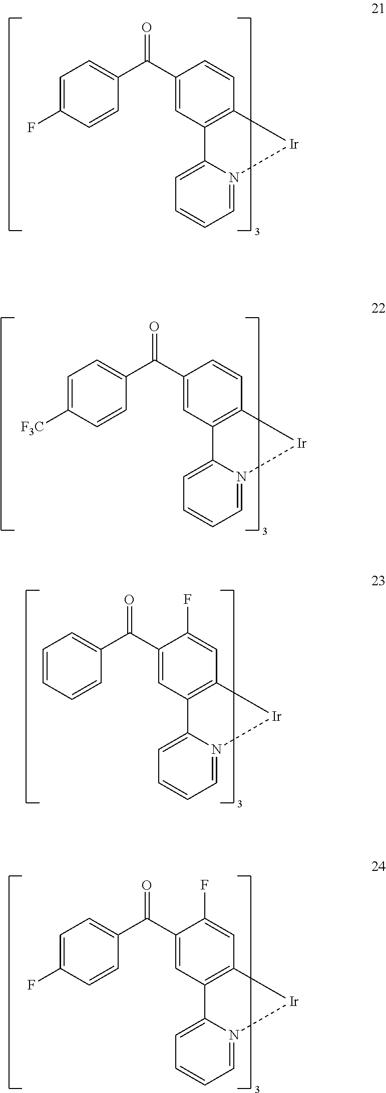

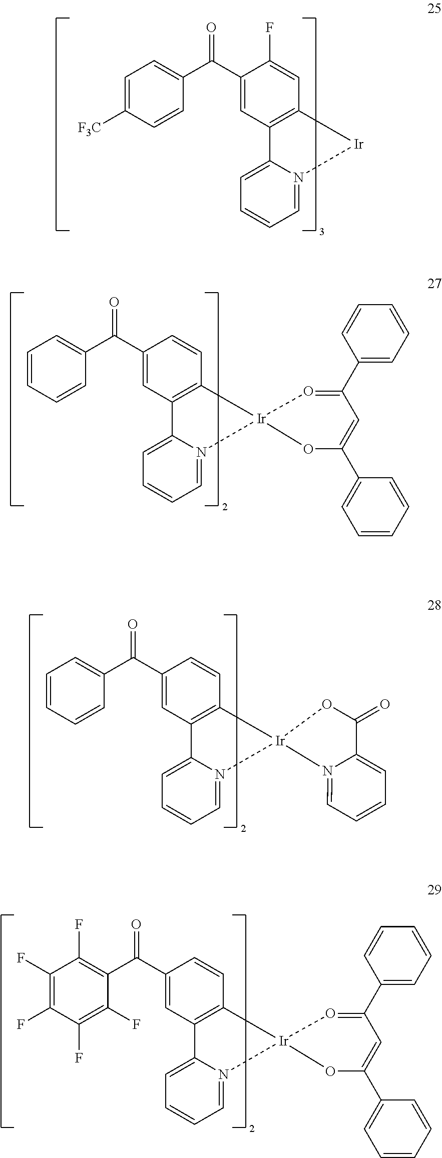

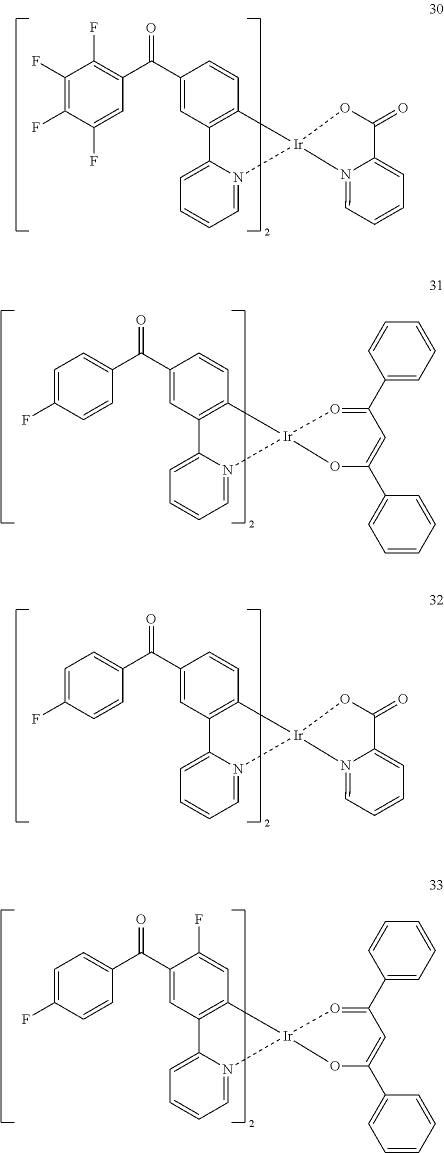

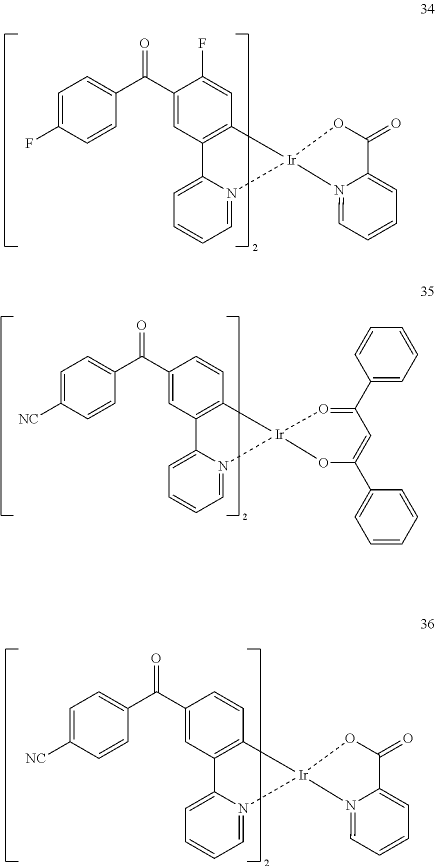

Physical properties of Compounds 1, 2, 4, and 5, above, and physical properties of Comparative Compounds 1 to 3, below, are described in the following Table 1.

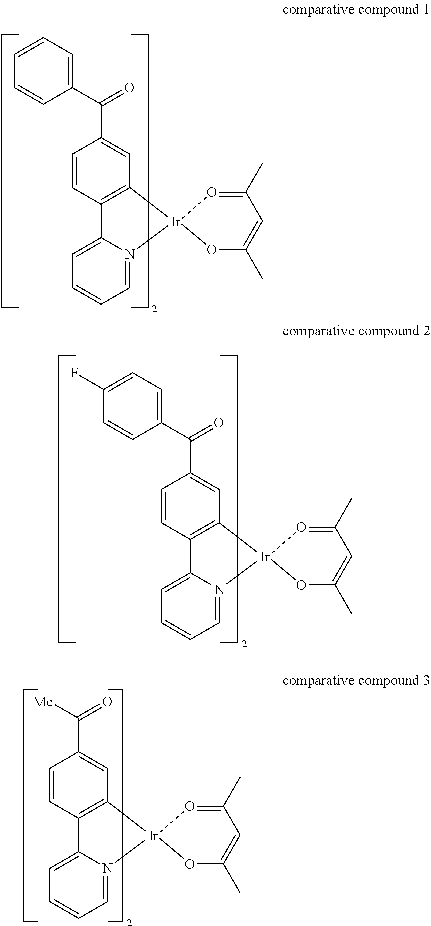

TABLE 1

| | λ_{PL}/nm | Φ_{PL} |
|---|---|---|
| Compound 1 | 502 | 0.716 |
| Compound 2 | 202 | 0.711 |
| Compound 4 | 485 | 0.457 |
| Compound 5 | 484 | 0.430 |
| Comparative Compound 1 | 607 | 0.081 |
| Comparative Compound 2 | 608 | 0.061 |
| Comparative Compound 3 | 589 | 0.130 |

In Table 1, λ_{PL} represents a wavelength (nm) of light generated from the compound, and Φ_{PL} represents a fluorescence quantum yield. Herein, dichloromethane was used as the solvent. The fluorescence quantum yields of Compounds 1, 2, 4, and 5 were about 0.716, 0.711, 0.457, and 0.430, and all had the numerical value of about 0.4 or more. From Table 1, it is apparent that the fluorescence quantum yields thereof are higher than those of Comparative Compounds 1, 2, and 3. Therefore, emission efficiency of Compounds 1, 2, 4, and 5 (as the organic electroluminescence material of according to an embodiment) having a characteristic that the organic electroluminescence material has the phenylcarbonyl substituent at the para position (position 5′ on the phenyl group and/or position 4 on the pyridine ring) of phenylpyridine coordinated with Ir (III) may be improved, as compared to the Ir (III) complex compound not having the aforementioned characteristic.

With respect to the organic electroluminescence material according to an embodiment, an example of a synthesis method of Compound 1 will be described below. However, the synthesis method is only exemplary.

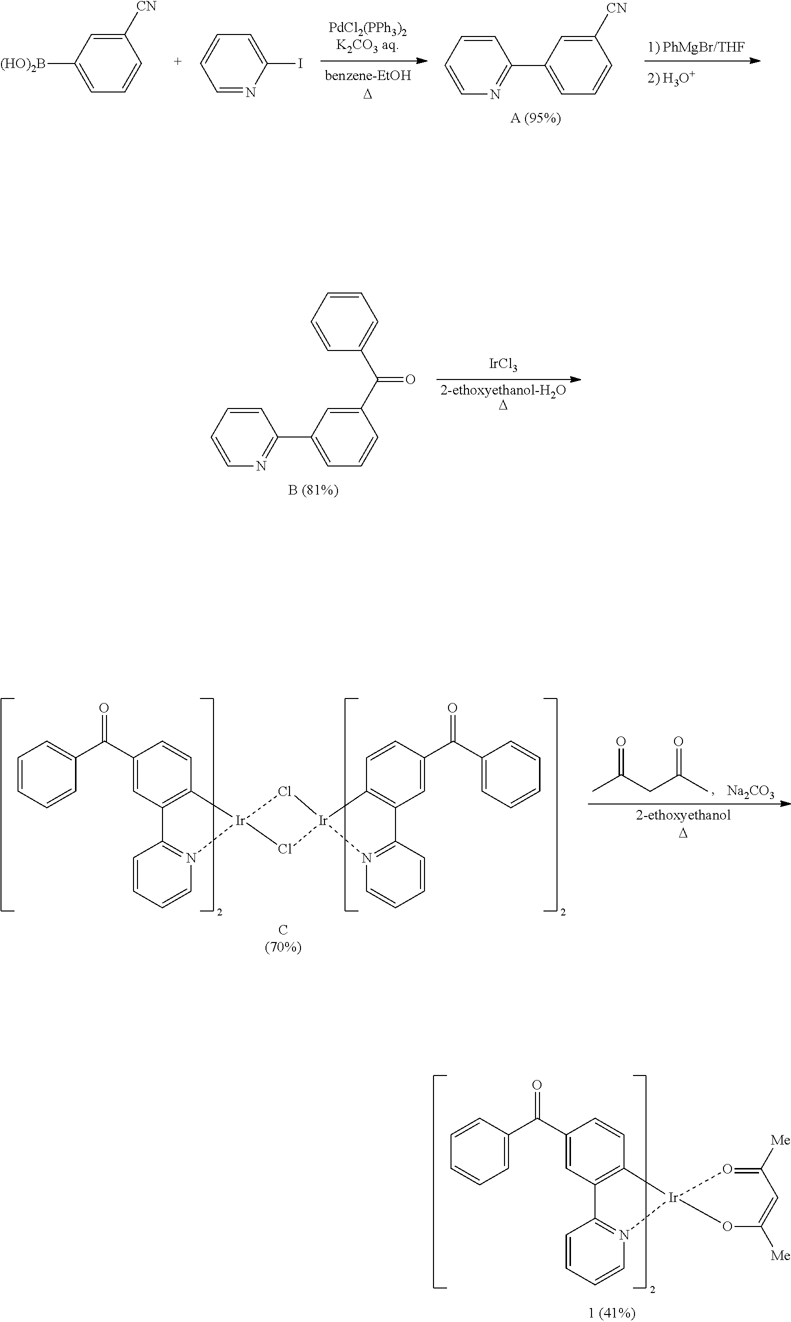

First, a mixture of a 3-cyano-phenylboric acid (about 0.268 g, about 1.83 mmol), 2-iodopyridine (about 0.25 g, about 1.22 mmol), (PPh₃)₂PdCl₂ (about 0.0689 g, about 0.0982 mmol), and potassium carbonate (about 1.69 g, about 12.3 mmol) was added to a 100 mL, 3-neck flask equipped with the cooling pipe, and under a nitrogen atmosphere. Benzene (about 5 mL), water (about 5 mL), and ethanol (about 2 mL) were sequentially added, and the flask was agitated under the nitrogen atmosphere, and heated and refluxed for about 24 hours. After cooling, the reaction mixture was concentrated with a rotary evaporator, methylene chloride (about 100 mL) was added to the remaining solid-liquid mixture and shaken in a separatory funnel, and the aqueous layer was then removed. The organic layer was washed with water (about 50 mL×2) and a saturated saline solution (about 100 mL) and dried with anhydrous magnesium sulfate. Solvent was then removed by distillation using the rotary evaporator. The remaining material was purified by silica gel column chromatography (developing solvent: methylene chloride) to obtain compound A (2-(3-cyanophenyl)pyridine) as a white solid in an amount of about 0.210 g with a yield of about 95%.

Subsequently, in a 100 mL 3-neck flask equipped with the cooling pipe, compound A (about 0.366 g, about 2.03 mmol) was dissolved in dry THF (about 4 mL), and the atmosphere was purged to be substituted with nitrogen, and phenylmagnesium bromide (about 0.5 M in THF, about 12 mL) was dripped little by little while being agitated at ambient temperature. Thereafter, the reaction mixture was refluxed while being heated for about 5 hours. After cooling, about 1 M sulfuric acid aqueous solution was added to allow the reaction solution to have acidity, and agitated at ambient temperature for about 2 hours. Thereafter, neutralization was performed with a saturated sodium hydrogenchloride aqueous solution (about 30 mL), and the reaction mixture was concentrated with a rotary evaporator. Methylene chloride (about 100 mL) was added to the remaining aqueous solution and shaken in a separatory funnel, and the aqueous layer was then removed. The organic layer was washed by water (about 50 mL×2) and a saturated saline solution (about 100 mL), and dried with anhydrous magnesium sulfate, and the solvent was removed by being distilled with rotary evaporator. The remaining material was purified by silica gel column chromatography (developing solvent: ethyl acetate/hexane=1/3) to obtain compound B (phenyl(3-(pyridine-2-yl)phenyl)methanone) as an oil-phase liquid having an ivory color in an amount of about 0.424 g at a yield of about 81%.

Subsequently, a mixture of compound B (about 0.188 g, about 1.05 mmol) and iridium chloride (about 0.154 g, about 0.487 mmol) was agitated in a mixture solvent of 2-ethoxyethanol (about 14 mL) and water (about 5 mL) under a nitrogen atmosphere, and heated and refluxed for about 17 hours. After cooling, the reaction mixture was added to water (about 100 mL), and the precipitated solid was separated by filtration with suction. The obtained solid was washed with ethanol and hexane in a small amount and dried at reduced pressure to obtain compound C (μ-chloro crosslinked iridium 2-nucleus complex) as a yellow solid in an amount of about 0.215 g at a yield of about 70%. Compound C was sparingly soluble in most solvents, novel purification was not performed, and compound C was used in the next reaction in a crude product state.

Next, a mixture of compound C (about 0.195 g, about 0.134 mmol), acetyl acetone (about 0.0401 g, about 0.400 mmol), and sodium carbonate (about 0.118 g, about 1.17 mmol) was agitated in 2-ethoxyethanol (about 30 mL) under a nitrogen atmosphere, and heated and refluxed for about 2 hours. After cooling, the reaction solvent was removed by being distilled in a rotary evaporator, and methylene chloride (about 50 mL) was added to the remaining material. Thereafter, the obtained mixture was washed by water (about 50 mL×2) and a saturated saline solution (about 100 mL) in a separatory funnel, and dried with anhydrous sodium sulfate. The solvent was then removed by being distilled using a rotary evaporator. The remaining material was purified using alumina column chromatography (developing solvent: methylene chloride/hexane=3/1) to obtain Compound 1 as a yellow solid in an amount of about 0.0873 g at a yield of about 41%.

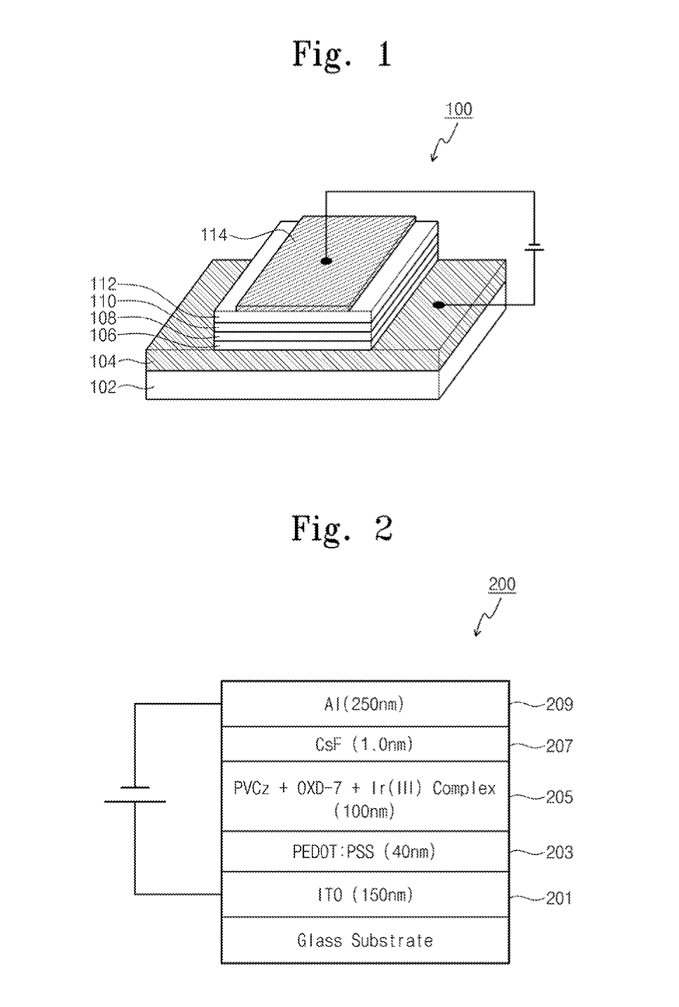

The organic electroluminescence material according to an embodiment, e.g., having the phenylcarbonyl substituent at the para position (position 5′ on the phenyl group and/or position 4 on the pyridine ring) of phenylpyridine coordinated with Ir (III) may be used in an emission layer of the organic EL device. For example, the organic EL device may have the structure illustrated in FIG. 1. As illustrated in FIG. 1, an organic EL device 100 may include, e.g., a glass substrate 102, a positive electrode 104 disposed on the glass substrate 102, a hole injection layer 106 disposed on the positive electrode 104, a hole transport layer 108 disposed on the hole injection layer 106, an emission layer 110 disposed on the hole transport layer 108, an electron transport layer 112 disposed on the emission layer 110, and a negative electrode 114 disposed on the electron transport layer 112. In an implementation, the electron transport layer 112 may serve as an electron injection layer. A suitable material may be used as a material of each layer. Further, according to the material constituting each layer, a predetermined layer in each of the layers may be omitted, and a layer other than each of the layers may be added. If the organic electroluminescence material according to an embodiment is used or included in the emission layer of the organic EL device, emission efficiency of the organic EL device may be improved. In an implementation, the organic electroluminescence material according to an embodiment may be included in any suitable layer of the organic EL device.

Hereinafter, an organic EL device in which Compounds 1 and 4 were used as in the emission layer will be described, e.g., as in FIG. 2.

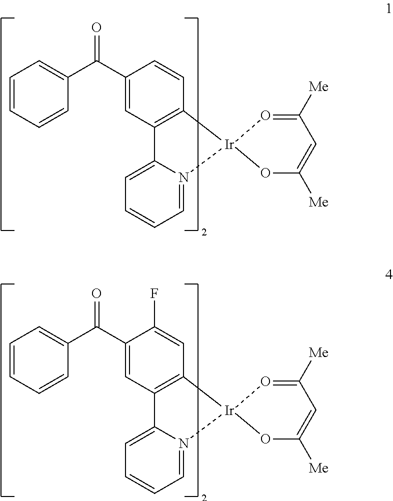

The organic EL device was manufactured according to the following procedure. First, the ITO-glass substrate (products manufactured by Sanyo Vacuum Industries, Co., Ltd., ITO film thickness was about 150 nm) patterned in advance and subjected to washing treatment was subjected to surface treatment by using ozone. After ozone treatment, immediately, a film of poly(3,4-ethylenedioxythiophene):poly(styrene-4-sulfonate) (PEDOT:PSS, products P CH 8000 manufactured by Heraeus Clevios™, film thickness was about 40 nm) as a hole injection material was formed on ITO by a spin coating method, and calcined at about 110° C. for about 1 hour. Next, a film of an emission layer in which 2-(4-biphenylyl)-5-(4-tert-butylphenyl)-1,3,4-oxadiazole (commonly called OXD-7) as an electron transport material, Compound 1 or 4 (Ir (III) complex) as an electroluminescence material, and poly(9-vinylcarbazole) (hereinafter, PVCz) as a hole transport host material were dissolved in dehydrated (dry) toluene (products manufactured by Wako Pure Chemical Industries, Ltd.) was formed (about 100 nm) by a spin coating method, and calcined at about 80° C. for about 1 hour. Then, cesium fluoride (about 1.0 nm) as an electron injection material and aluminum (about 250 nm) as a negative electrode were sequentially laminated by vacuum deposition method using a shadow mask having an emission area of about 0.10 cm² to manufacture the organic EL device 200. The obtained organic EL device 200 was sealed together with a drying material in a cavity glass using the UV-curable resin. As the composition of the emission layer, the PVCz:OXD-7:Ir complex was set in a content of about 10:3.0:1.2 (wt/wt/wt).

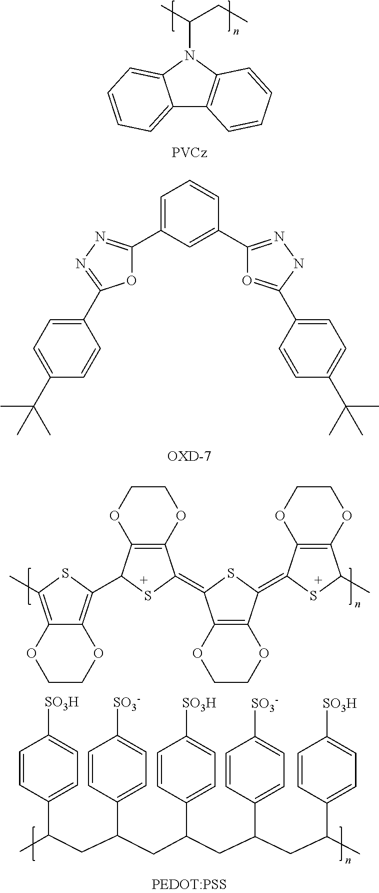

A schematic view of the manufactured organic EL device 200 is illustrated in FIG. 2. The manufactured organic EL device 200 may include a positive electrode 201, a hole injection layer 203 disposed on the positive electrode 201, an emission layer 205 disposed on the hole injection layer 203, an electron injection layer 207 disposed on the emission layer 205, and a negative electrode 209 disposed on the electron injection layer 207. Herein, the emission layer 205 may have both functions of the hole transport layer and the electron transport layer.

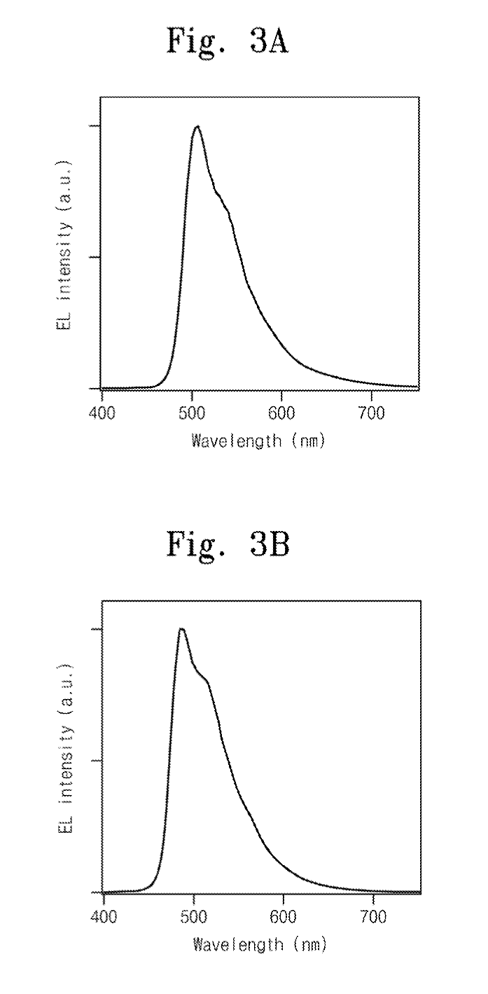

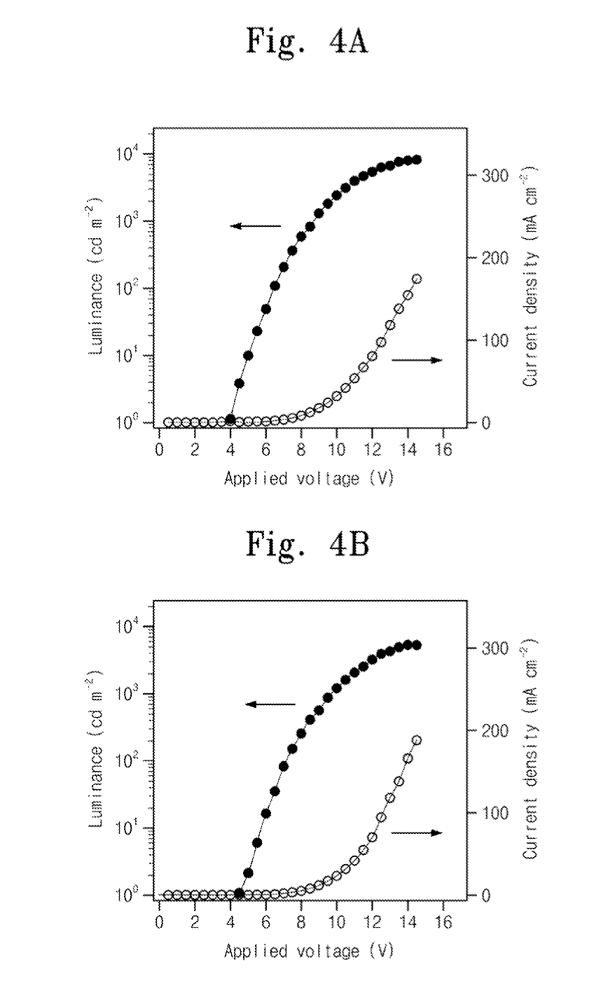

EL spectra of the manufactured organic EL device 200 are illustrated in FIGS. 3(a) and 3(b). FIG. 3(a) illustrates the EL spectrum of the organic EL device 200 where Compound 1 was used in the emission layer 205, and FIG. 3(b) illustrates the EL spectrum of the organic EL device 200 where Compound 4 was used in the emission layer 205. The EL spectra were measured at maximum brightness of the organic EL device 200. Further, current density-voltage-brightness curves (J-V-L curve) of the manufactured organic EL device 200 are illustrated in FIGS. 4(a) and 4(b). FIG. 4(a) illustrates the J-V-L curve of the organic EL device 200 where Compound 1 was used in the emission layer 205, and FIG. 4(b) illustrates the J-V-L curve of the organic EL device 200 where Compound 4 was used in the emission layer 205.

Device performance of the manufactured organic EL device 200 is shown in the following Table 2.

TABLE 2

| | Vₜᵤᵣₙ₋ₒₙ^{a} | L^{b} | ηₑₓₜ^{b} | ηⱼ^{b} | ηₚ^{b} | CIE | λ_{EL} |
|---|---|---|---|---|---|---|---|
| Compound | (V) | (cd m⁻²) | (%) | (cd A⁻¹) | (lm W⁻¹) | (x, y) | (nm) |
| 1 | 4.0 | 8210 [14.5] | 2.44 [10.0] | 7.67 [10.0] | 2.81 [7.5] | (0.27, 0.60) | 507 |
| 4 | 4.5 | 6090 [14.5] | 2.13 [10.0] | 5.70 [10.0] | 2.07 [8.0] | (0.21, 0.50) | 485 |

^{a}1 cd m⁻² A voltage when light is emitted.
^{b}The maximum value (value in [ ]) of each efficiency represents a voltage (V) when the value is represented.

In evaluation of the electroluminescence property of the manufactured organic EL device 200, a brightness orientation property measurement apparatus C9920-11 manufactured by HAMAMATSU Photonics K. K. was used.

By way of summation and review, as an organic electroluminescence material used in an emission layer of an electroluminescence device (hereinafter, referred to as ‘organic EL device’), a phosphorescent electroluminescence material which can emit light from a triplet excitation state has been considered. In the case where the phosphorescent electroluminescence material is used in the emission layer of the organic EL device, quantum efficiency may be significantly improved, and emission efficiency of the organic EL device may be improved. As the phosphorescent electroluminescence material, metal complex compounds including heavy atoms such as iridium, platinum, rhodium, and ruthenium may be used, and examples thereof may include many materials by various combinations of central metal and ligands. For example, an iridium complex compound having an organic ligand such as a phenylpyridine derivative may be used.

In application of the organic EL device to displays, high efficiency may be required in the organic electroluminescence material. For example, a blue electroluminescence material may have emission efficiency that is lower than that of a red electroluminescence material and a green electroluminescence material, and an improvement of emission efficiency may be desirable.

According to an embodiment, it is possible to provide an organic EL device having improved emission efficiency, and an organic electroluminescence material having improved emission efficiency to realize the same.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic electroluminescence material represented by the following Chemical Formula 1: 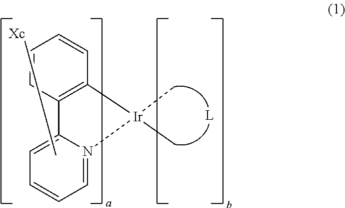
wherein, in Chemical Formula 1, X is a phenylcarbonyl group represented by the following Chemical Formula 2, L is a bidentate ligand represented by one of the following Chemical Formulae 3 to 5, a is 1, 2, or 3, b is 0, 1, or 2, a sum total of a and b is 3, and c is 1 or 2, 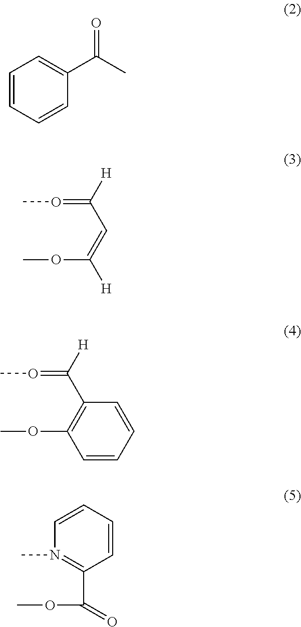
Chemical Formulae 1 to 5 are unsubstituted or substituted, in which case a hydrogen atom thereof is replaced with one of a fluorine atom, a trifluoromethyl group, a cyano group, a nitro group, an alkyl group having 6 or fewer carbon atoms, an aryl group having 6 or fewer carbon atoms, or a heteroaryl group having 6 or fewer carbon atoms.

2. The organic electroluminescence material as claimed in claim 1, wherein the phenylcarbonyl group is bonded at a para position of the phenyl group or the pyridine group, relative to the coordination bond of the phenyl group or the pyridine group with Ir in Chemical Formula 1.

3. The organic electroluminescence material as claimed in claim 1, wherein a fluorescence quantum yield of the material is about 0.4 or more.

4. An organic electroluminescence device, comprising an organic electroluminescence material represented by the following Chemical Formula 1: 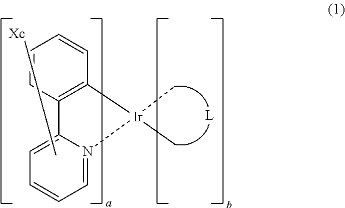
wherein, in Chemical Formula 1, X is a phenylcarbonyl group represented by the following Chemical Formula 2, L is a bidentate ligand represented by one of the following Chemical Formulae 3 to 5, a is 1, 2, or 3, b is 0, 1, or 2, a sum total of a and b is 3, and c is 1 or 2, 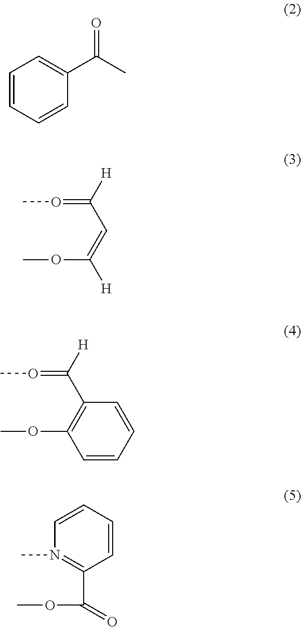
Chemical Formulae 1 to 5 are unsubstituted or substituted, in which case a hydrogen atom thereof is replaced with one of a fluorine atom, a trifluoromethyl group, a cyano group, a nitro group, an alkyl group having 6 or fewer carbon atoms, an aryl group having 6 or fewer carbon atoms, or a heteroaryl group having 6 or fewer carbon atoms.

5. The organic electroluminescence device as claimed in claim 4, wherein the phenylcarbonyl group is bonded at a para position of the phenyl group or the pyridine group, relative to the coordination bond of the phenyl group or the pyridine group with Ir in Chemical Formula 1.

6. The organic electroluminescence device as claimed in claim 4, wherein a fluorescence quantum yield of the material is about 0.4 or more.
